(19) United States
(12) Patent Application Publication
(10) Pub. No.: US 2012/0289006 A1
(43) Pub. Date: Nov. 15, 2012

(54) METHOD OF MANUFACTURING POLY-SILICON TFT ARRAY SUBSTRATE

(75) Inventor: Guangcai YUAN, Beijing (CN)

(73) Assignee: BOE TECHNOLOGY GROUP CO., LTD., Beijing (CN)

(21) Appl. No.: 13/468,280

(22) Filed: May 10, 2012

(30) Foreign Application Priority Data
May 13, 2011 (CN) 201110124667.9

(51) Int. Cl. H01L 21/336

(52) U.S. Cl. 438/158; 257/E21.409

(57) ABSTRACT

An embodiment of the present disclosure relates to a method of manufacturing a poly-silicon TFT array substrate, which accomplishes a patterning process to form a gate electrode, a poly-silicon semiconductor pattern and a pixel electrode with one process by using an HTM or GTM mask.

### BACKGROUND

The present disclosure relates to a method of manufacturing a poly-silicon thin film transistor (TFT) array substrate.

Low temperature poly-silicon (LTPS) technology is initially used to decrease energy consumption of a notebook computer's display screen. Approximately in the middle of 1990s, this technology that is developed for making a notebook computer thinner and lighter began to be placed into application. At present, also a new generation of organic light-emitting diode (OLED) display panel based on the LTPS technology has stepped into a practical stage, with the advantages of ultra-thin profile, light weight, low power consumption, and self-illumination, and thereby can provide more beautiful colors and clearer images.

Below will explain a method of manufacturing a poly-silicon TFT array substrate in a conventional technology with reference to FIG. 1 and FIGS. 2A-2F.

FIG. 1 is a flow chart of an existing method of manufacturing a poly-silicon TFT array substrate. FIGS. 2A-2F are cross-sectional views in the procedure of manufacturing a poly-silicon TFT array substrate.

S101, forming a poly-silicon film.

As shown in FIG. 2A, a buffer layer 12 of silicon dioxide (SiO₂) is formed on the entire surface of an insulating substrate 11 by using a plasma enhanced chemical vapor deposition (PECVD) method. Subsequently, an amorphous silicon (a-Si) film is formed on the entire surface of the buffer layer 12 by using a PECVD method or the like. Thereafter, a poly-silicon thin film 22 is finally formed by crystallizing the a-Si film through a procedure of LTPS processing.

S102, forming a gate electrode.

As shown in FIG. 2B, the poly-silicon layer is subject to a patterning process to form a semiconductor layer pattern 13, and a layer of inorganic material (SiO₂) is then deposited on the entire surface of the semiconductor layer pattern 13 to form a gate insulting layer 14. Next, a low-resistance metal layer is deposited on the gate insulting layer 14, and is then subject to a patterning process to form a gate line with a gate electrode 15a.

S103, implanting impurity ions into the poly-silicon.

As shown in FIG. 2C, with the gate electrode 15a as a mask, n-type impurity ions of a high concentration are doped into the semiconductor layer pattern 13, thus source and drain regions 13a and 13c are formed. Herein, the semiconductor layer between the source region 13a and the drain region 13c, in which the impurity ions are not doped due to the existence of the gate electrode 15a, will work as a channel layer 13b.

S104, forming an interlayer dielectric layer.

As shown in FIG. 2D, an inorganic material layer (SiO₂) is deposited on the entire surface including the gate electrode 15a by chemical vapor deposition (CVD) method, thereby forming an interlayer dielectric layer 16.

S105, activating the poly-silicon.

The surface of the semiconductor layer pattern 13 is subject to a rapid thermal annealing (RTA) process, a laser beam irradiation with an excimer laser, or a thermal annealing process inside a furnace, thereby activating the semiconductor layer 13.

S106, forming a source electrode and a drain electrode.

After the activation process is accomplished in step S105, as shown in FIG. 2E, the gate insulting layer 14 and the interlayer dielectric layer 16 are etched to expose the source and drain regions 13a and 13c, thereby forming first contact holes 20a and 20b. To etch the gate insulating layer 14 and the interlayer dielectric layer 16, dry etching is commonly carried out. Next, as shown in FIG. 2F, a low-resistance metal layer is deposited on the interlayer dielectric layer 16 and then is subject to a patterning process to form a data line perpendicular to the gate line and form a source electrode 17a and a drain electrode 17b. The source and drain electrodes 17a and 17b are in contact with the source and drain regions 13a and 13c, respectively.

S107, hydrogenating the poly-silicon.

A layer of inorganic material such as silicon nitride (SiNx) is deposited on the entire surface including the source and drain electrodes 17a and 17b by a chemical vapor deposition (CVD) method, thereby forming a passivation layer 18, and then the substrate is heated into a range of heat-resistant temperature thereof for diffusing hydrogen atoms contained in the passivation layer 18 into the semiconductor layer.

S108, forming a pixel electrode.

The passivation layer 18 is selectively removed so as to expose the drain electrode 17b, thereby forming a second contact hole 40, and a pixel electrode 37 is formed in a pixel region in such a manner that the pixel electrode 37 is in contact with the drain electrode 17b via the second contact hole 40.

It can be seen that, the existing poly-silicon TFT array substrate and the manufacturing method thereof employs exposure masks at least 6 times in total during formation of a semiconductor layer pattern, a gate line layer, first contact holes, a data line layer, a second contact hole, and a pixel electrode. The increased using times of exposure masks results in complicated processes, increased processing time and costs.

### SUMMARY

An embodiment of the present disclosure provides a method of manufacturing a poly-silicon TFT array substrate, which can reduce the numbers of the used masks for manufacturing a LTPS TFT array substrate and thereby decrease complexities of processes and reduce processing time and costs.

An embodiment of the present disclosure provides a method of manufacturing a poly-silicon TFT array substrate, comprising the following steps:

S401, forming a buffer layer on a base substrate;

S402, forming a poly-silicon layer on the buffer layer;

S403, forming a gate insulting layer on the poly-silicon layer;

S404, forming a composite gate electrode layer on the gate insulting layer; and

S405, with a half-tone mask or a gray-tone mask, performing a patterning process to the laminated layers of the composite gate electrode layer, the gate insulting layer, and the poly-silicon layer through a same one patterning process to obtain patterns of a gate electrode, a poly-silicon semiconductor and a pixel electrode.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a flow chart of a method of manufacturing a poly-silicon TFT array substrate in a conventional technology;

FIGS. 2A-2F are the schematic views of manufacturing a poly-silicon TFT array substrate in the conventional technology;

FIG. 3A is a schematic view of photoresist exposure with an HTM mask in an embodiment of the present disclosure;

FIG. 3B is a schematic view of photoresist exposure with a GTM mask in an embodiment of the present disclosure;

FIG. 4 is a flow chart of a method of manufacturing a poly-silicon TFT array substrate according to an embodiment of the present disclosure; and

FIGS. 5A-5P are the first to sixteenth schematic views of manufacturing a poly-silicon TFT array substrate according to an embodiment of the present disclosure.

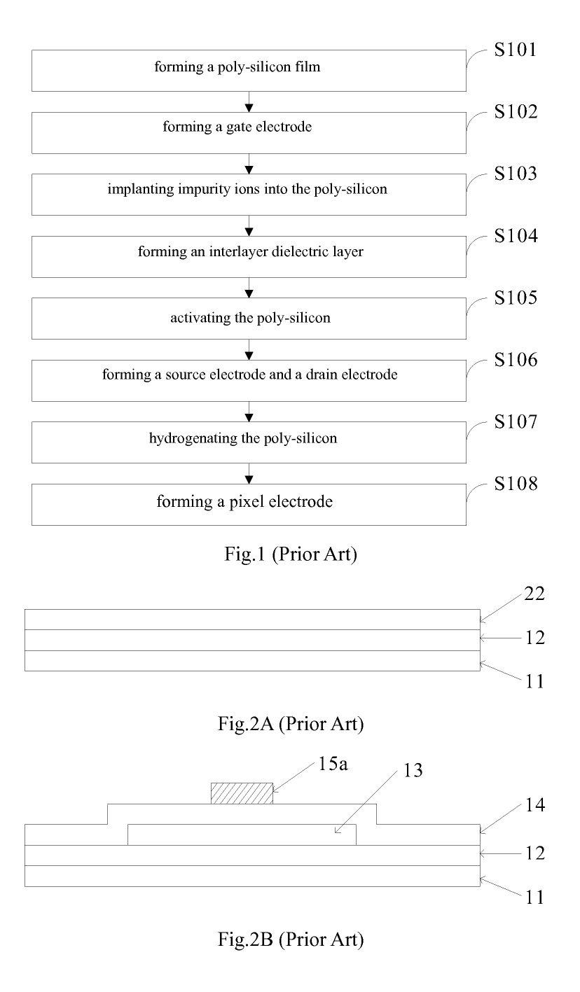

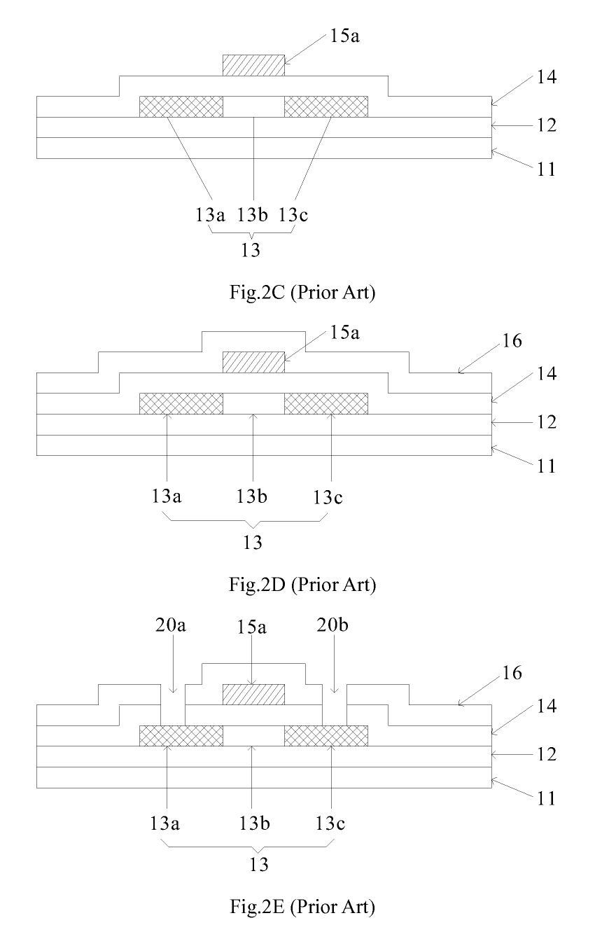

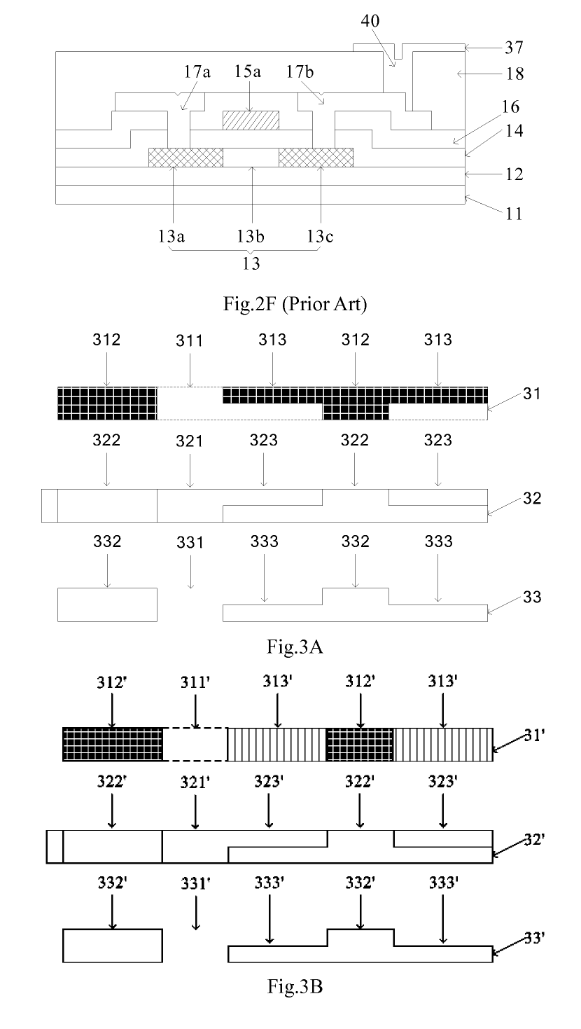

### DETAILED DESCRIPTION

Below the embodiments of the present disclosure will be fully and clearly described in conjunction with the accompanying drawings. Apparently, the described embodiments are not the all embodiments but only a part of embodiments of the present disclosure. Based on the embodiments of the present disclosure, all other embodiments obtained by the ordinary skilled in the art without creative efforts, fall in the protection scope of the present disclosure.

The technology employed in the embodiments of the present disclosure can involve a half-tone mask (HTM) or a gray-tone mask (GTM), a dual-layer electrode and advance formation of pixel electrode. The patterns of a gate electrode, a poly-silicon semiconductor and a pixel electrode can be obtained in one patterning process, thereby decreasing the usage times of mask in the procedure of manufacturing an LTPS array substrate, thus lowering costs, reducing processing steps and improving mass production yield rate.

In an embodiment of the present disclosure, with an HTM or GTM process, different etching means can be used, such as first wet etching to etch the composite gate electrode layer (e.g., including a metal layer and an ITO layer) and then dry etching or wet etching an underlying non-metal after the completion of the above-described etching of the metal layer, and the etching targets include the gate insulating layer and the poly-silicon (Poly-Si), this step of etching can realize a patterning process with respect to a poly-silicon active layer and a pixel electrode. Such patterning process may comprise steps of applying photoresist on a target layer, exposing the photoresist, developing to obtain a photoresist pattern, and etching with the photoresist pattern, and so on, thereby forming pattern in the target layer.

After completion of the above-described steps, the corresponding photoresist in the source/drain (S/D) region experienced HTM or GTM process is removed through an ashing process, and the corresponding gate metal in the ashing region is then etched away through a dry etching process, thus accomplishing a patterning process for the poly-silicon film, the gate electrode and the pixel electrode through one mask is realized.

When the method according to the embodiment of the present disclosure is applied to manufacture of a top gate type LTPS TFT, in order to overcome the influence of the ashing procedure and the etching process after the ashing procedure upon the exposed sidewalls of the poly-silicon layer, the patterns of the active layer (e.g., poly-silicon) may be further designed to slightly wider than that in the conventional technology in which the poly-silicon pattern and the gate electrode are formed in two separate patterning process, and the pattern width of the active layer pattern may be about 0.5-1.0 μm, which can effectively overcome the potential disadvantage influence of the three masking on the characteristics of the LTPS TFT.

In the embodiment of the present disclosure, through a process involving a dual-layer electrode (e.g., a metal layer and an indium tin oxide (ITO) layer), the patterning process to form a gate electrode line and a pixel electrode can be accomplished with one mask, while the pixel electrode is not completed in this procedure. The pixel electrode will finally be completed in such a step that the pixel electrode region is formed when a data line is formed, and this step of process does not increase the number of the used masks.

In addition, in a preferred example of the embodiment of the present disclosure, the connections of the components can be accomplished with one through-hole processing, and the etching of the through-holes are only performed with respect to one passivation layer, which can overcome risks caused by multi-layers' etching in formation of through-holes in the conventional technology, and thus production yield rate can be further increased.

For the periphery protection of signal lines and the pixel electrode, a design layer mask for an OLED, for example, can be provided.

Below, in conjunction with the accompanying drawings, the manufacturing method in the embodiments of the present disclosure and an HTM mask and a GTM mask will be further explained.

### Embodiment 1

The method of manufacturing a poly-silicon TFT array substrate according to embodiment 1 of the present disclosure will be explained with by taking using a half-tone mask (HTM) to manufacture a low temperature poly-silicon TFT array substrate for example.

Firstly, with reference to FIG. 3A, the main principle of the HTM process will be explained. FIG. 3A illustrates a photoresist exposing process with an HTM mask 31. The HTM mask 31 comprises a transparent region 311, opaque regions 312 and partially-transparent regions 313. The photoresist 32 is in an exposed state, in which the region 321 corresponds to the transparent region 311 of the HTM mask 31, and the regions 322 correspond to the opaque regions 312 of the HTM mask 31, and the regions 323 correspond to the partially-transparent regions 313 of the HTM mask 31. The photoresist 33 is in a developed state, in which the region 331 corresponds to the transparent region 311 of the HTM mask 31, and the regions 332 correspond to the opaque regions 312 of the HTM mask 31, and the regions 333 correspond to the partially-transparent regions 313 of the HTM mask 31.

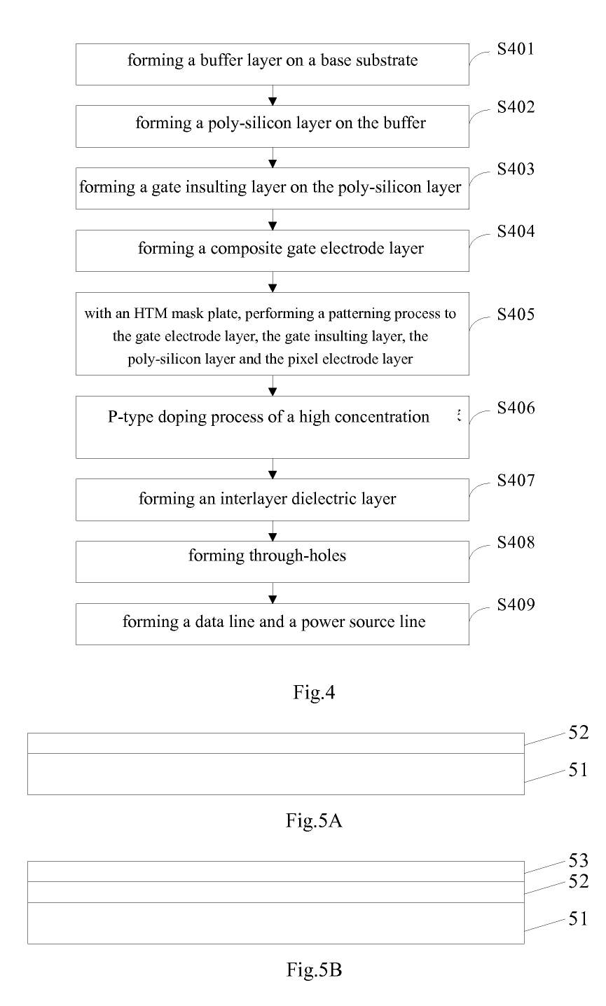

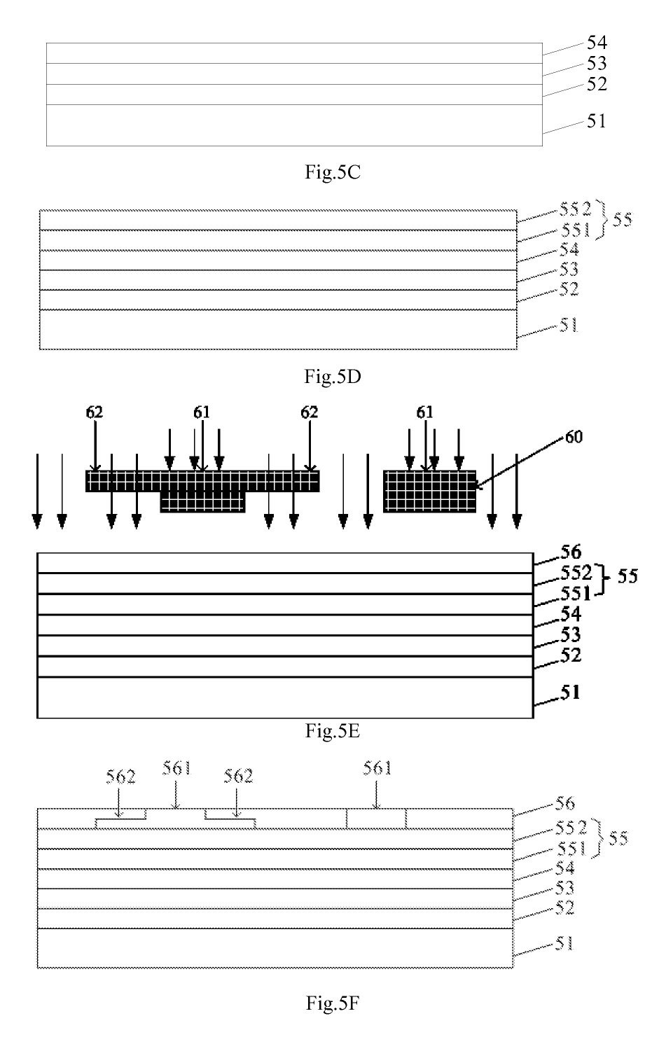

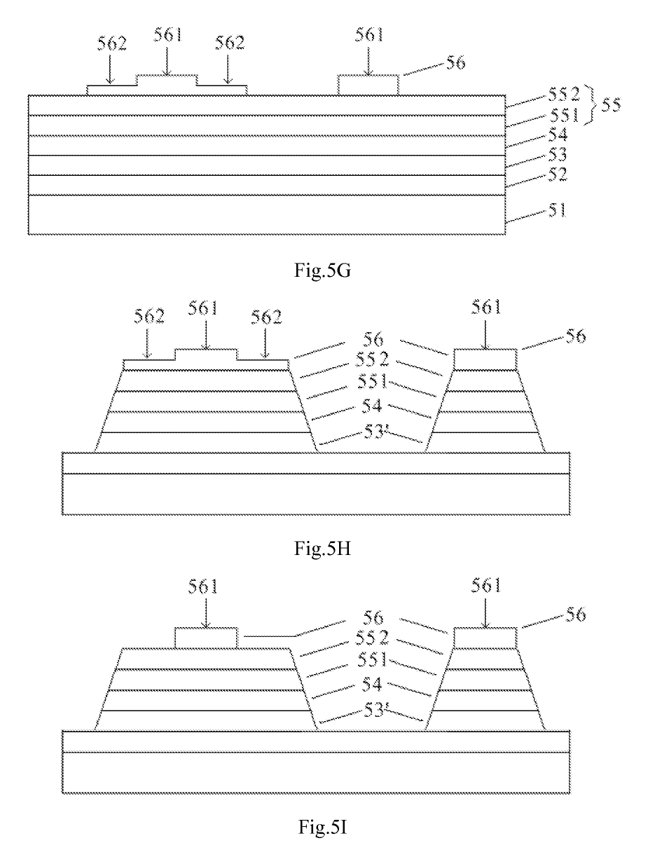

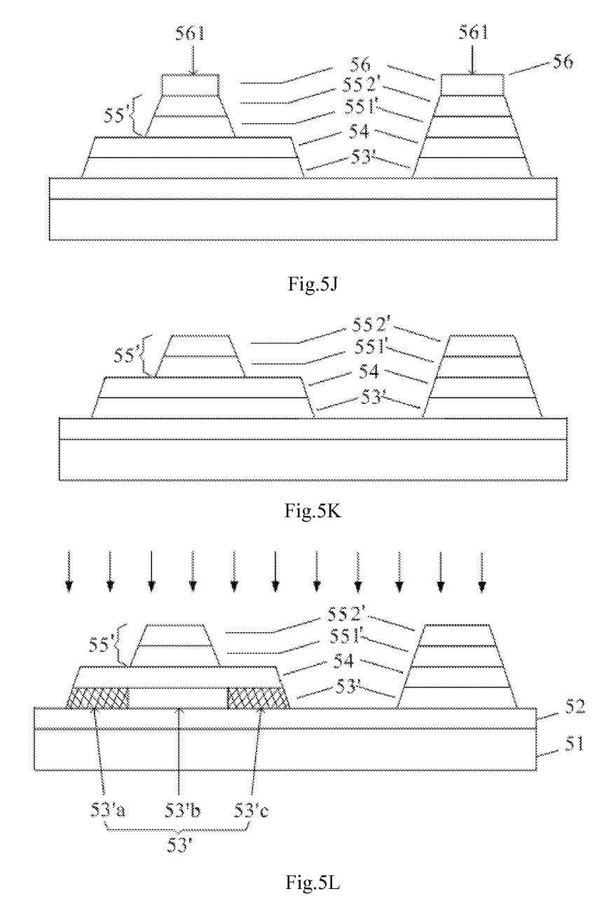

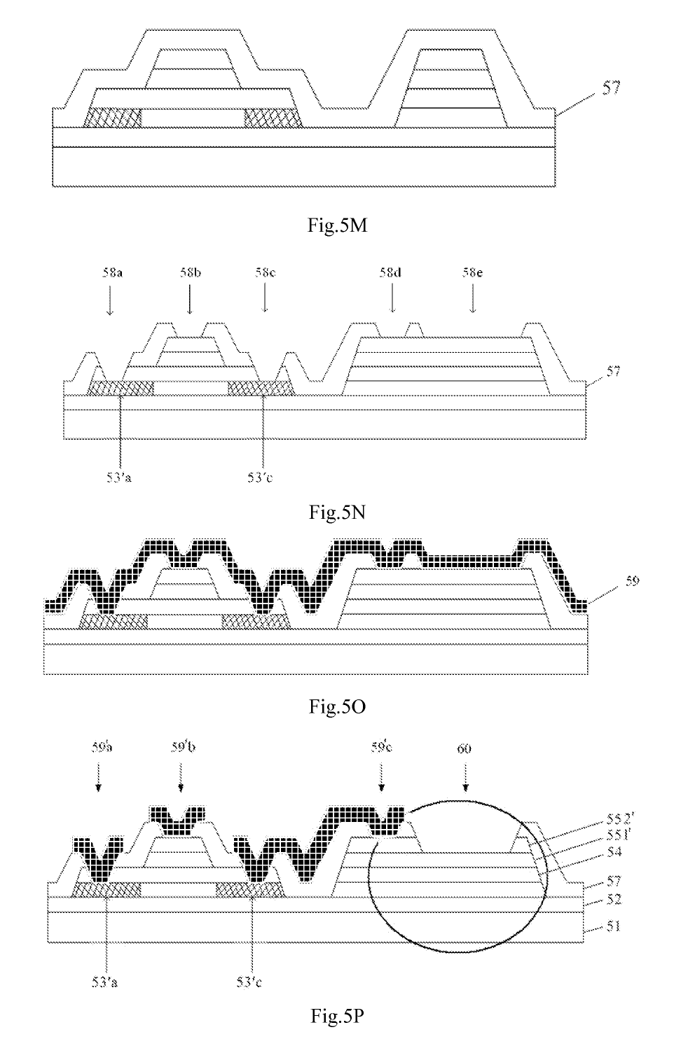

Below, with reference to FIG. 4 and FIGS. 5A-5P, a method of manufacturing a poly-silicon TFT array substrate with an HTM mask according to an embodiment of the present disclosure will be explained.

S401, forming a buffer layer on a base substrate.

Specifically, the base substrate such as a glass substrate is at first cleaned through an initial cleaning process, and cleanness grade will be in accordance with the grade of particles≦300 ea (particle size≧1 μm), and the thickness of the glass substrate may be in the range of 0.3-0.7 mm. In order to prevent harmful substances contained in the glass substrate such as alkali metal ions and other impurities from affecting performances of the poly-silicon thin film layer later formed thereon, a PECVD method is adopted to deposit a buffer layer on the glass substrate, and pre-cleaning is conducted prior to the deposition of a buffer layer. The base substrate may be a plastic substrate or a silica substrate.

As shown in FIG. 5A, the glass substrate 51 is covered with a buffer layer 52. In this embodiment, the buffer layer may comprise two parts. First, a SiNx thin film is deposited with a thickness about 50-100 nm, which can inhibit the metal atoms and impurities in the glass substrate from affecting the poly-silicon thin film. In order to prevent the impact of defect states in the SiNx film on the crystallization quality of the poly-silicon thin film, a SiO₂ layer in a thin film form with a thickness about 100-150 nm, which can match with the poly-silicon thin film, is deposited on the SiNx thin film. After preparation, the buffer layer may be subject to an annealing and surface treatment so as to optimize the quality of the buffer layer.

S402, forming a poly-silicon layer on the buffer layer.

As shown in FIG. 5B, with a PECVD method, on the buffer layer 52 there is deposited an amorphous silicon layer with a thickness of 40-60 nm, which gives rise to a poly-silicon layer 53 after a crystallization process.

For example, after an amorphous silicon layer is deposited on the buffer layer with a PECVD method, a dehydrogenation process may be carried out upon the amorphous silicon layer by using high-temperature oven annealing or rapid thermal annealing (RTA) at temperature of 400-500° C., to prevent hydrogen explosion during the later crystallization procedure and reduce defect state density inside the thin film after crystallization. After dehydrogenation process is completed, an LTPS process is carried out to perform poly-crystallization process upon the a-Si thin film. Crystallization means such as excimer laser annealing (ELA) process, metal induced crystallization (MIC) process, solid phase crystallization (SPC) process and the like are methods commonly used to perform crystallization process upon an amorphous silicon layer. After crystallization, a cleaning process may be also carried out to perform surface treatment to a poly-silicon thin film layer by using DHF (Dimethyl dihydroxy fumarate, purity of 1-10%) or diluted HF (hydrofluoric acid) chemical agents, which can lower the surface roughness of the poly-silicon thin film layer, and remove wrinkles or point protrusions or the like caused by crystallization, so that the poly-silicon thin film layer can be in better contact with the subsequently formed thin film layer, and can improve performances of the whole device.

S403, forming a gate insulting layer on the poly-silicon layer.

As shown in FIG. 5C, on the processed poly-silicon layer 53, a gate insulting layer 54 is deposited by using a PECVD method, for example. The insulating layer 54 may be a SiO₂ (40-100 nm)/SiNx (80-150 nm) composite thin film, or may adopt a single layer of SiO₂ (100-200 nm) thin film.

S404, forming a composite gate electrode layer on the gate insulting layer.

As shown in FIG. 5D, on the gate insulting layer 54, a composite gate electrode layer 55 with a thickness of 200-400 nm is formed by a sputtering method. The composite gate electrode layer comprises a transparent conductive layer (e.g., an ITO layer) 551 and a metal layer 552. The thickness of the ITO layer 551 is in the range of 40-150 nm, and the thickness of the metal layer 552 is in the range of 150-350 nm. The material of the metal layer 552 in the gate electrode layer may be Al, Mo, Al—Nd alloy, W or the like electrode material, or may be composite layer of Al/Mo or Mo/Al—Nd/Mo. The part of the ITO layer in the pixel electrode region will be used to form a pixel electrode. In another example, the transparent conductive layer may be an indium zinc oxide (IZO) layer or the like.

S405, with an HTM mask, performing a patterning process to the laminated layers of the gate electrode layer, the gate insulting layer, the poly-silicon layer and the pixel electrode layer, so that a gate electrode, a poly-silicon semiconductor pattern and a pixel electrode portion can be obtained.

As shown in FIG. 5E, a layer of photoresist 56 is applied onto the base substrate with the formed layer structure and then subject to an exposing process with an HTM mask 60. The HTM mask 60 is used for TFT and pixel electrode region, in which the portions corresponding to the gate electrode and the pixel electrode region are opaque regions 61, and the portions corresponding to the source and drain electrode regions are partially-transparent regions 62, and the rest regions are transparent regions.

FIG. 5F is a schematic view of the photoresist 56 in an exposed state, in which the regions 561 of the photoresist 56 correspond to the opaque regions 61 of the HTM mask 60, and the regions 562 of the photoresist 56 correspond to the partially-transparent regions 62 of the HTM mask 60, and the rest regions correspond to the transparent regions of the HTM mask 60. The photoresist 56 may positive photoresist.

FIG. 5G is a schematic view of the photoresist 56 in a developed state, in which the regions 561 of the photoresist 56 are photoresist-fully-remained regions, and the regions 562 of the photoresist 56 are photoresist-partially-remained regions, and the other regions are photoresist-completely-removed regions.

Next, as shown in FIG. 5H, through a wet etching process, the gate electrode layer 55 in the photoresist-completely-removed regions is etched, and then through a dry etching process, the gate insulting layer 54 and the poly-silicon layer 53 in the photoresist-completely-removed regions are etched, thereby a poly-silicon semiconductor portion 53′ are obtained. The processing procedure may be adjusted, and for instance, a combination of a first dry etching and then a wet etching, or a mixed etching processes, or the like process may be adopted.

Thereafter, through a plasma ashing process, the photoresist-partially-remained regions 562 of the photoresist 56 are removed, but the photoresist-fully-remained regions 561 is partially left, as shown in FIG. 5I; the photoresist-fully-remained regions 561 correspond to the gate electrode and the pixel electrode regions.

Then, as shown in FIG. 5J, through a dry etching or a wet etching process, the gate metal layer of the photoresist-partially-remained region 562 is subject to a second etching process.

As shown in FIG. 5K, after the photoresist-fully-remained region 561 of the photoresist 56 is removed, a composite portion 55′ including a gate electrode and a pixel electrode regions is obtained, which are an ITO layer electrode 551′ and a metal layer electrode 552′, respectively.

So far, in the embodiment of the present disclosure, through one HTM mask process, a patterning process is accomplished to obtain the gate electrode, the poly-silicon semiconductor pattern and the pixel electrode portion. Compared with the conventional technology in which firstly one patterning process is carried out to obtain a portion of the poly-silicon semiconductor, then a second patterning process is carried out to obtain a gate electrode, and subsequently a third patterning process is carried out to obtain a pixel electrode, the embodiment of the present disclosure reduces two masking processes with a mask, thereby reducing complexities of processes, reducing manufacturing time and manufacturing costs.

Further, in contrast to the conventional technology in which three mask processes are used to achieve a poly-silicon semiconductor pattern, a gate electrode and a pixel electrode, in this embodiment the poly-silicon semiconductor pattern can be slightly enlarged, for example, to the width of about 0.5-1.0 μm, which will effectively overcome the potential impact of the reduced mask processes on characteristics of the LTPS TFT.

Furthermore, in the embodiment of the present disclosure, the connection of various components can be achieved through one through-hole process, and the whole array manufacturing procedure can use only three patterning process (three masking process), of which an specific preferred embodiments is:

S406, P-type doping process of a high concentration is carried out with respect to the source and drain regions of the poly-silicon semiconductor.

As shown in FIG. 5L, with a method of self-alignment process, by way of ions bath or ions implantation, BHx (B₂H₆/H₂ with mixing ratio of 5˜10% or BF₃) is doped into the source and drain regions 53′a, 53′c, with doping dose of 1˜5×10¹⁵ cm⁻² and doping energy of 5˜100 KeV. Due to the existence of the gate electrode 55′, the region of the poly-silicon layer between the source region 53′a and the drain region 53′c in which impurity ions are not doped, becomes a channel layer 53′b.

S407, forming an interlayer dielectric layer.

As shown in FIG. 5M, through a PECVD process, an interlayer dielectric layer 57 is formed; the thin film material may be a composite SiNx/SiO₂, SiNx or SiO₂ thin film, and the thickness may be 300-500 nm. Subsequently, through a rapid thermal annealing (RTA) process, the doped ions is activated; at the same time, the hydrogen contained in the gate insulating layer and the interlayer dielectric layer of SiNx, the hydrogenation of the poly-silicon layer can be achieved during the RTA activation procedure. With this method, manufacturing steps of the whole process can be reduced, such as the subsequent H₂ plasma hydrogenation procedure.

S408, forming through-holes.

As shown in FIG. 5N, through a second patterning process, through-holes 58a-58e are formed, thus the source and drain regions 53′a, 53′c of the thin film transistor is exposed through the through-holes 58a, 58c, and at the same time the gate electrode's through-hole 58b, a part of the through-hole 58e of the pixel electrode, and the through-hole 58d connecting the pixel electrode and the source and drain are formed. In addition, although not shown in the figure, this step also forms through-holes at respective positions of a data line for exposing the data line, so that the data line and a driver can be connected through a subsequent process.

S409, forming a data line and a power source (VDD) line.

A metal layer 59 for the data line and the VDD line is formed by a sputtering evaporation method, and the metal layer may be Mo, Al, Al—Mo, Mo/Nd—Al/Mo or the like with a thickness of 300-400 nm, as shown in FIG. 5O. After formation of the above-mentioned structure, through a third patterning process, signal lines such as the data line, VDD lines and the like and connecting lines 59′a, 59′b, 59′c for various components can be obtained, as shown in FIG. 5P. After the above described through-holes are obtained, by increasing etching (dry etching or wet etching) time, the metal layer 552 on the ITO 551 in the pixel electrode region is etched away, thereby forming the pixel electrode region 60 through one etching process.

Here, in the example, a dual-layer electrode is adopted mainly for forming an ITO electrode in contact with OLED for example, which can reduce contacting resistance and potential barrier between the electrode and OLED, and at the same time a metal-to-metal connection is provided for the contacting points at the data lines and the pixel electrodes. Such method also alleviates the problem of too large contacting resistance due to direct connection of metal and ITO, which are belong to different type of conductive materials. Since the dual-layer electrode is formed in succession, with no transition layer formed therebetween, the potential barrier and the contacting resistance between the ITO layer and the metal layer will also be reduced. This can effectively overcome a signal-delay problem of a large size display device, thus can effectively improve display quality of a panel. The formed array substrate can be used for an OLED display device or a LCD device.

Moreover, compared with the conventional technology of obtaining through-holes by multiple etching steps, the embodiment of the present disclosure forms through-holes through one insulating layer in manufacturing, which can effectively improve etching efficiency, and make great progress in increasing production yield rate and so on.

### Embodiment 2

The method of manufacturing a poly-silicon TFT array substrate according to embodiment 2 of the present disclosure will be explained with an example of using a gray-tone mask (GTM) to manufacture a low temperature poly-silicon TFT array substrate.

Firstly, with reference to FIG. 3B, the main principle of the GTM process will be explained. A GTM mask employs grating effect, so that light of different intensity passes through the mask at different regions, thereby selectively exposing and developing photoresist. FIG. 3B illustrates a photoresist exposing process with a GTM mask 31′. The GTM mask 31′ comprises a transparent region 311′, opaque regions 312′ and partially-transparent regions 313′. The photoresist 32′ is in an exposed state, in which the region 321′ corresponds to the transparent region 311′ of the GTM mask 31′, and the regions 322′ correspond to the opaque regions 312′ of the GTM mask 31′, and the regions 323′ correspond to the partially-transparent regions 313′ of the GTM mask 31′. The photoresist 33′ is in an after-develop state, in which the region 331′ corresponds to the transparent region 311′ of the GTM mask 31′, and the regions 332′ correspond to the opaque regions 312′ of the GTM mask 31′, and the regions 333′ correspond to the partially-transparent regions 313′ of the GTM mask 31′.

In the embodiment 2, compared with the embodiment 1, except the step S405 in which the patterning process step with a GTM is slightly different from the patterning process step with an HTM in the embodiment 1, the other steps are the same as those in the embodiment 1, which can be understood with reference to FIGS. 5A-5P; therefore, the relevant description is omitted.

In the method of manufacturing a poly-silicon TFT array substrate according to various embodiments of the present disclosure, after a poly-silicon layer, a gate insulting layer, and a gate electrode layer are formed on a base substrate, with an HTM or a GTM mask, in one patterning process, the patterns of a gate electrode and a poly-silicon semiconductor and a pixel electrode can be directly obtained. Compared with the prior art in which firstly one patterning process is carried out to obtain a poly-silicon semiconductor pattern, then a second patterning process is carried out to obtain a gate electrode, and subsequently a third patterning process is carried out to obtain a pixel electrode, the present disclosure reduces two processes of exposing with a mask. Moreover, the whole array substrate manufacturing procedure of the present disclosure can only employ three patterning processes to obtain the TFT array substrate; in contrast, six patterning processes are needed to form a TFT array substrate in the conventional technology, which greatly reduces complexities of processes, thereby reducing manufacturing time and manufacturing costs.

Compared with the conventional technology, the embodiments of the present disclosure can obtain a TFT array substrate through only three masking processes with HTM or GTM technology, which greatly improves production efficiency, alleviates the problem of decreased production yield rate due to complex processing steps in the conventional technology. With three masking processes, the embodiments of the disclosure can reduce the difficulties in processes, and increase the production yield rate, further the problem of high costs for LTPS processes can be solved; that is, the application of the present disclosure can greatly reduce production costs and increase production yield rate.

The above embodiments are only used to explain the present disclosure, instead of limit the present disclosure. The ordinary skilled in the related art, without departing from the spirit and the scope of the present disclosure, can also make many modifications and variations, therefore all equivalent technical schemes should belong to the present disclosure, and the actual protection scope of the present disclosure should be defined as the claims.

What is claimed is:

1. A method of manufacturing a poly-silicon thin film transistor (TFT) array substrate, comprising the steps:
forming a buffer layer on a base substrate;
forming a poly-silicon layer on the buffer layer;
forming a gate insulting layer on the poly-silicon layer;
forming a composite gate electrode layer on the gate insulting layer;
with a half-tone mask or a gray-tone mask, performing a patterning process to the laminated layers of the composite gate electrode layer, the gate insulting layer, and the poly-silicon layer through a same one patterning process to obtain patterns of a gate electrode, a poly-silicon semiconductor and a pixel electrode.

2. The method according to claim 1, wherein performing a patterning process to the laminated layers of the composite gate electrode layer, the gate insulting layer, and the poly-silicon layer through a same one patterning process to obtain patterns of a gate electrode, a poly-silicon semiconductor and a pixel electrode with a half-tone mask or a gray-tone mask, comprises:
applying photoresist on the laminated layers of the composite gate electrode layer, the gate insulting layer, and the poly-silicon layer;
with the half-tone mask or the gray-tone mask, exposing photoresist and developing to form a photoresist-fully-remained region, a photoresist-partially-remained region and a photoresist-completely-removed region, wherein the photoresist-fully-remained region corresponds to the gate electrode and the pixel electrode, and the photoresist-partially-remained region corresponds to source and drain regions;
removing the composite gate electrode layer, the gate insulting layer, and the poly-silicon layer in the photoresist-completely-removed region through an etching process;
removing the photoresist in the photoresist-partially-remained region through a plasma ashing process;
removing the composite gate electrode layer in the photoresist-partially-remained region through an etching process; and
removing the photoresist in the photoresist-fully-remained region.

3. The method according to claim 1, wherein in the half-tone mask or gray-tone mask, the regions corresponding to the gate electrode and the pixel electrode are opaque regions, and the regions corresponding to the TFT source and drain regions are partially-transparent regions, and the rest regions are transparent regions.

4. The method according to claim 1, wherein the composite gate electrode layer is a composite dual-conductive layer structure comprising a transparent conductive layer and a metal layer, and the transparent conductive layer is formed before the metal layer.

5. The method according to claim 1, wherein the thickness of the poly-silicon semiconductor pattern is in a range of 40-100 nm.

6. The method according to claim 4, wherein the thickness of the metal layer of the composite gate electrode layer is in a range of 150-350 nm, and the thickness of the transparent conductive layer is in a range of 40-150 nm.

7. The method according to claim 4, wherein the transparent conductive layer comprises indium tin oxide or indium zinc oxide.

8. The method according to claim 1, after performing a patterning process, further comprising:
performing a doping process with respect to the source and drain regions of the poly-silicon semiconductor portion, thereby forming source and drain regions.

9. The method according to claim 8, wherein the doping process comprises:
doping BHx into the source and drain regions by way of ions bath or ions implantation through a self-alignment process method.

10. The method according to claim 8, after performing a doping process, further comprising:
forming an interlayer dielectric layer, and activating doped ions through an annealing process and at the same time hydrogenating the poly-silicon semiconductor portion.

11. The method according to claim 10, after forming an interlayer dielectric layer, further comprising:
forming through holes on the source and drain regions, and forming a pixel electrode through-hole on the pixel electrode; and
forming a data line, a power source line, and connection lines on the base substrate; and
etching away the corresponding metal layer in the pixel electrode region with a dry etching or a wet etching, so as to make the pixel electrode in the pixel electrode region exposed.

12. The method according to claim 1, wherein three patterning processes are performed, in which one through-hole processing is performed to realize connections of various components.

13. The method according to claim 4, wherein the material of the metal layer comprises Al, Mo, W, Al/Mo, Al—Nd alloy or Mo/Al—Nd/Mo.
